(19) United States
(12) Patent Application Publication
(10) Pub. No.: US 2010/0176486 A1
(43) Pub. Date: Jul. 15, 2010

(54) Semiconductor device and method of manufacturing the same

(75) Inventors: Takashi Miyajima, Tokyo (JP); Shigeru Sugioka, Tokyo (JP); Kazushi Komeda, Tokyo (JP); Takashi Miyamura, Tokyo (JP); Kohei Inoue, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/654,929

(22) Filed: Jan. 8, 2010

(30) Foreign Application Priority Data
Jan. 13, 2009 (JP) P2009-005038

(51) Int. Cl. H01L 29/92; H01L 21/02

(52) U.S. Cl. 257/532; 438/387; 257/296; 438/239; 257/E21.011; 257/E29.342

(57) ABSTRACT

A semiconductor device includes a memory cell region and a peripheral circuit region. The memory cell region includes a first region and a second region surrounding the first region. The first region includes a plurality of first electrodes, a plurality of first support portions, and a second support portion. The plurality of first electrodes upwardly extends. The plurality of first support portions upwardly extends along the plurality of first electrodes. Each of the plurality of first support portions mechanically supports corresponding one of the plurality of first electrodes. The second support portion contacts with the plurality of the first support portions. The second support portion connects between each of the plurality of first electrodes.

### BACKGROUND OF THE INVENTION

1. Field of the Invention

The present invention relates to a semiconductor device and a method of manufacturing the same. More specifically, the present invention relates to a semiconductor device and a method of manufacturing the same for preventing lower electrodes having a high aspect ratio from collapsing.

Priority is claimed on Japanese Patent Application No. 2009-005038, filed Jan. 13, 2009, the content of which is incorporated herein by reference.

2. Description of the Related Art

Recently, components forming a semiconductor device have been shrunk with further miniaturization of semiconductor devices. For example, regarding DRAM (Dynamic Random Access Memory) including memory cell regions and a peripheral circuit region, an area of the memory cell has been decreased.

Generally, a capacitor formed in the memory cell is in a three-dimensional shape so as to have enough capacitance. Specifically, a lower electrode of the capacitor is made in a cylindrical shape to increase an area of a surface of the lower electrode. Additionally, a height of the lower electrode is increased for achieving enough capacitance.

However, the lower electrode is more unstable as the aspect ratio is larger, thereby causing the lower electrode to easily collapse, and therefore to short-circuit to another lower electrode in the memory cell region, for example, when outer sidewalls of the lower electrodes are exposed by a wet etching process that is one of semiconductor device manufacturing processes.

Additionally, a longer etching time for the etching process is required as the aspect ratio is larger. For this reason, the semiconductor device has to be subjected to an etching solution for etching for a long time, thereby causing the etching solution to penetrate into a peripheral circuit region, and therefore causing malfunction of the peripheral circuit.

To prevent lower electrodes from collapsing, for example, Japanese Patent Laid-Open Publication No. 2003-297952 discloses a semiconductor device including a cylindrical capacitor and a method of manufacturing the same. The semiconductor device includes a frame for supporting lower electrodes to prevent lower electrodes from collapsing.

Japanese Patent Laid-Open Publication No. 2003-142605 discloses a semiconductor device and a method of manufacturing the same. The semiconductor device includes an insulating pedestal member for supporting bottom surfaces of lower electrodes and an insulating beam connecting side surfaces of the lower electrodes.

However, the support member disclosed in any of the above related art only contacts the side surfaces of the lower electrodes. For this reason, when sidewalls of the lower electrodes are exposed in the wet etching process, the support member is also etched, thereby decreasing the connection strength of a portion connecting the support member and the lower electrodes.

Particularly when heights of the lower electrodes are increased to increase the capacitance of the capacitor, an etching time for the etching process has to be longer. For this reason, the support member is further etched, thereby further decreasing the connection strength of the portion connecting the support member and the lower electrodes, and therefore causing the lower electrodes to easily collapse.

Further, if an etching time for the wet etching process, i.e., a time for the semiconductor device to be subjected to an etching solution, is set to be longer, the etching solution penetrates into the peripheral circuit region, thereby causing malfunction of the peripheral circuit.

### SUMMARY

In one embodiment, a semiconductor device includes a memory cell region and a peripheral circuit region. The memory cell region includes a first region and a second region surrounding the first region. The first region includes a plurality of first electrodes, a plurality of first support portions, and a second support portion. The plurality of first electrodes upwardly extends. The plurality of first support portions upwardly extends along the plurality of first electrodes. Each of the plurality of first support portions mechanically supports corresponding one of the plurality of first electrodes. The second support portion contacts with the plurality of the first support portions. The second support portion connects between each of the plurality of first electrodes.

In another embodiment, a method of manufacturing a semiconductor device includes the following processes. A plurality of first openings and a first groove are formed in a first insulating layer so as to penetrate the first insulating layer. The first groove surrounds the plurality of first openings. Then, a plurality of first electrodes and a first groove wall are formed. The plurality of first electrodes covers at least side surfaces of the plurality of first openings. The first groove wall covers at least a side surface of the first groove. Then, a first support film is formed on the plurality of first electrodes and the first groove wall. Then, a plurality of first support portions, a second support portion, a third support portion, and a fourth support portion are formed by removing a part of the first support film. Each of the plurality of first support portions is disposed in the plurality of first openings. The third support portion is disposed in the first groove. The second support portion contacts with each of upper surfaces of the plurality of first support portions. The fourth support portion contacts with an upper surface of the third support portion. The second support portion contacts with the fourth support portion. The second support portion connects between each of the plurality of first electrodes. Then, a part of the first insulating layer is removed to expose outer side walls of the plurality of first electrodes. Then, a second insulating layer is formed on a surface of the plurality of first electrodes. Then, a second electrode is formed on the second insulating layer.

Accordingly, the lower electrodes having a high aspect ratio can be prevented from collapsing. Therefore, the lower electrodes are prevented from short-circuiting caused by collapse of the lower electrodes.

Additionally, an etching solution can be prevented from penetrating into the peripheral circuit region adjacent to the memory cell region when the sidewalls of the lower electrodes in the memory cell region are exposed in one of the semiconductor device manufacturing processes. Therefore, a semiconductor device including a capacitor including lower electrodes having a high aspect ratio can be easily manufactured.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a plane view illustrating a semiconductor device according to a first embodiment of the present invention;

FIGS. 2, 3, 12 and 16 are plane views illustrating a memory cell region of the semiconductor device according to the first embodiment;

FIG. 4A is a cross-sectional view illustrating a main region of the memory cell region;

FIG. 4B is a cross-sectional view illustrating a cell peripheral region of the memory cell region;

FIGS. 5A to 15A are cross-sectional views taken along a line A-A′ shown in FIG. 2 indicative of a process flow illustrating a method of manufacturing the semiconductor device according to the first embodiment;

FIGS. 5B to 15B are cross-sectional views taken along a line B-B′ shown in FIG. 2 indicative of a process flow illustrating the method of manufacturing the semiconductor device according to the first embodiment;

FIGS. 17A to 21A are cross-sectional views taken along the line A-A′ indicative of a process flow illustrating a method of manufacturing a semiconductor device according to a second embodiment of the present invention; and

FIGS. 17B to 21B are cross-sectional views taken along the line B-B′ indicative of a process flow illustrating a method of manufacturing the semiconductor device according to the second embodiment of the present invention.

### DETAILED DESCRIPTION OF THE PREFERRED EMBODIMENTS

The invention will be now described herein with reference to illustrative embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

### First Embodiment

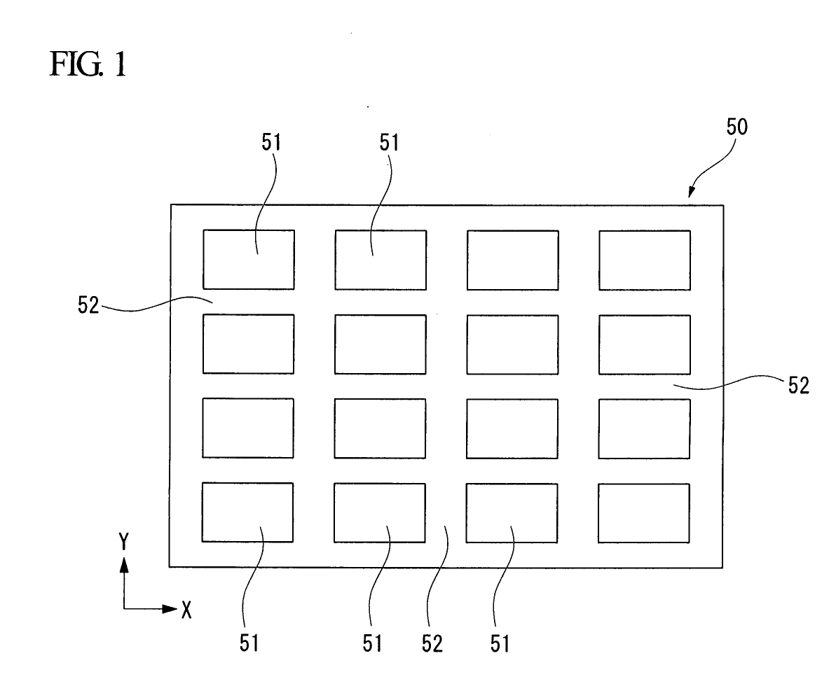

FIG. 1 is a plane view illustrating DRAM exemplifying a semiconductor device 50 according to a first embodiment of the present invention. The semiconductor device 50 (DRAM) is formed on a semiconductor substrate and includes: a plurality of memory cell regions 51 arranged in a grid; and a peripheral circuit region 52 surrounding each of the memory cell regions 51.

The semiconductor device 50 is rectangular if viewed in a direction perpendicular to upper and bottom surfaces of thereof. Hereinafter, an X direction indicates a direction of one side of the semiconductor device 50, and a Y direction indicates a direction perpendicular to the X direction.

Although not shown in FIG. 1, the peripheral circuit region 52 includes sense amplifier circuits, driving circuits such as word lines, I/O (Input-Output) circuits, and the like, but does not include a capacitor 30 for storing data. The number and arrangement of the memory cell regions 51 are not limited to those shown in FIG. 1.

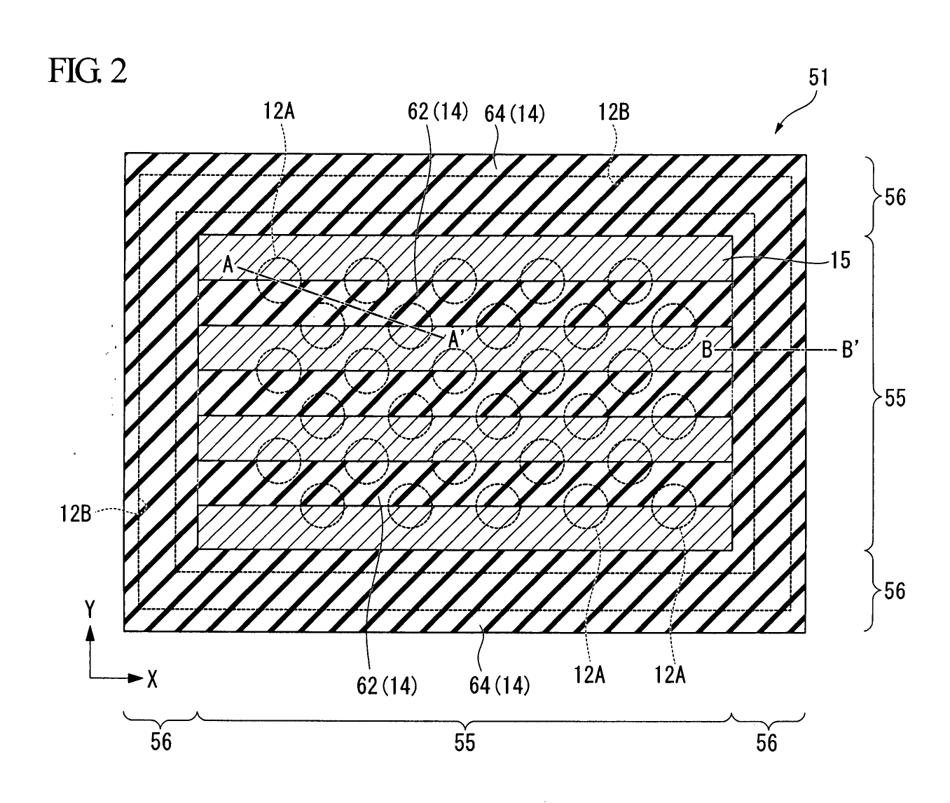

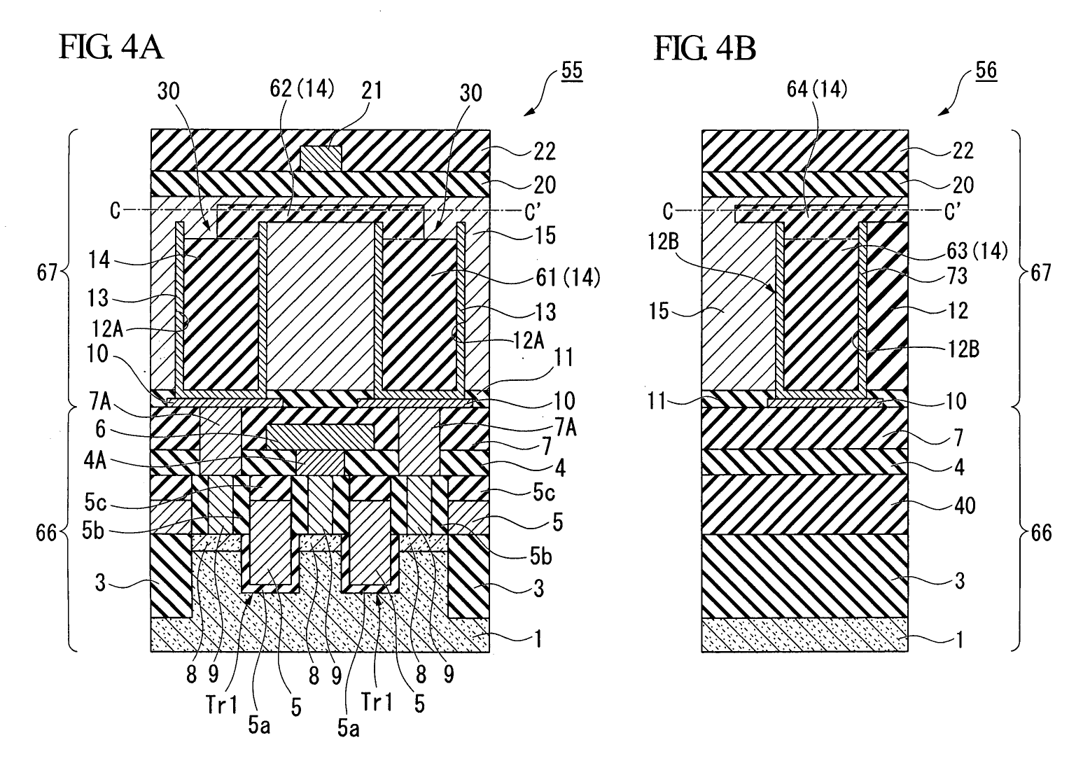

FIG. 2 is an enlarged plane view taken along a line C-C′ shown in FIG. 4 illustrating one of the memory cell regions 51 shown in FIG. 1. The memory cell region 51 includes a main region (first region) 55 and a cell peripheral region (second region) 56 surrounding the main region 55.

A fourth support portion 64 is formed in the cell peripheral region 56. A groove 12B formed under the fourth support portion 64 surrounds the main region 55. A cross-section taken along a line B-B′ is a cross-section of the cell peripheral region 56.

A plurality of second support portions 62 in a straight-line shape extend toward the X direction and contact two opposing sides of the fourth support portion 64. The lines of the second support portions 62 are above an upper electrode 15.

A plurality of circular openings 12A are arranged in a substantially grid in a capacitor formation layer 67 that will be explained later. The positions of the openings 12A are positions of capacitors. A cross-section taken along a line A-A′ is a cross-section of the main region 55.

The number and arrangement of the openings (capacitors) 12A are not limited to those shown in FIG. 2. The shape of the opening 12A is not limited to a circle, and may be an ellipse, a rectangle, a polygon, or the like.

The second support portion 62 partially covers each of the openings 12A, and is integrated with first support portions 61 filling the openings 12A, thereby strongly supporting the lower electrodes.

Additionally, the second support portion 62 contacts the fourth support portion 64 in the cell peripheral region 56, thereby strongly supporting the lower electrodes without easily collapsing. Thus, the second support portion 62 prevents the capacitors from collapsing in the semiconductor device manufacturing processes.

The shape and the extending direction of the second support portion 62 are not limited to those shown in FIG. 2. For example, the second support portion 62 may be arranged in a grid or in a net-like manner.

Additionally, a second support portion 62 not contacting the fourth support portion 64 may be included. Further, the shape of the second support portion 62 is not limited to a straight line, and may be a curved line.

Moreover, the second support portion 62 completely covering the openings 12A may be included. Additionally, a shape of a portion where the second support portion 62 overlaps the opening 12A may be different.

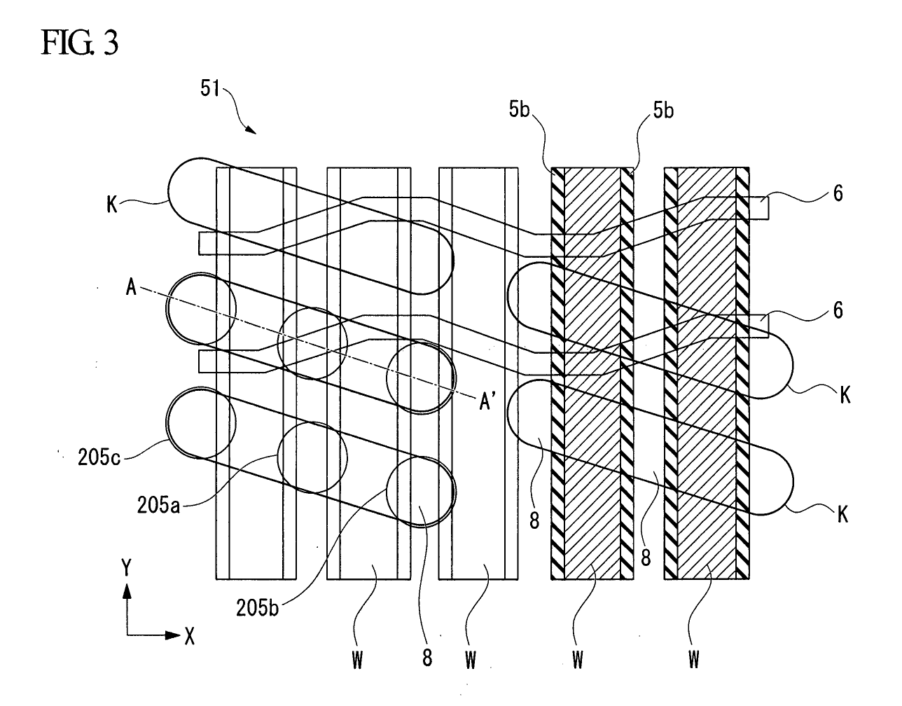

FIG. 3 is an enlarged plane view illustrating the memory cell region 51 shown in FIG. 2. The line A-A′ shown in FIG. 3 is the same as that shown in FIG. 2. A right side of FIG. 3 illustrates a transparent cross-section taken along a plane perpendicular to a gate electrode 5 and a sidewall 5b which will be a word wiring W.

Bit wirings 6 extending toward the X direction, word wirings W extending toward the Y direction, and strip active regions K are included in the memory cell region 51. The bit wirings 6 are curved lines extending toward the X direction, and arranged at a predetermined pitch along the Y direction.

The word wirings W are straight lines extending toward the Y direction, and arranged at a predetermined pitch along the X direction. A gate electrode (not shown) is disposed at a region where the word wiring W crosses each active region K.

The sidewall 5b is formed on either side of the word wiring W and extends toward the Y direction. The active regions K are arranged at a predetermined pitch and extend toward the right lower direction.

Circular substrate contact portions 205a, 205b, and 205c are formed on the center and both ends of the active region K. The centers of the substrate contact portions 205a, 205b, and 205c are positioned between the word wirings W. The center substrate contact portion 205a overlaps the bit wiring 6.

The substrate contact portions 205a, 205b, and 205c are portions at which substrate contact plugs are formed, and which are in contact with a semiconductor substrate. An impurity diffusion layer 8 is formed under an upper surface of the semiconductor substrate.

The semiconductor contact portions 205a, 205b, and 205c are formed immediately above the impurity diffusion layer 8, so that the impurity diffusion layers 8 function as S/D (source and/or drain) regions of MOS transistors Tr1. The shape and arrangement of the active region K are not limited to the specific ones shown in FIG. 3, and may be ones used for a general transistor.

FIG. 4A is a cross-sectional view taken along the line A-A′ shown in FIGS. 2 and 3 illustrating the semiconductor device 50. FIG. 4B is a cross-sectional view taken along the line B-B′ shown in FIG. 2. In other words, FIG. 4A is a cross-sectional view illustrating the main region 55. FIG. 4B is a cross-sectional view illustrating the cell peripheral region 56.

As shown in FIG. 4A, each of the main and cell peripheral regions 55 and 56 includes a capacitor formation layer 67 and a transistor formation layer 66 under the capacitor formation layer 67. The capacitor formation layer 67 includes two capacitors 30. The transistor formation layer 66 includes two MOS transistors Tr1.

The two capacitors 30 are connected to the two MOS transistors Tr1 through contact plugs. The two MOS transistors Tr1 include one of the active regions K which is defined by element isolation regions 3. Accordingly, the semiconductor device of the first embodiment can be used as DRAM including 2-bit memory cells.

The MOS transistors Tr1 include: the semiconductor substrate 1; the element formation regions 3; the active region K defined by the element formation regions 3; and two trench gate electrodes 5 in the active region K.

Silicon (Si) containing a P-type impurity at a predetermined concentration can be used for the semiconductor substrate 1. The element formation regions 3 are formed by embedding an insulating film, such as a silicon oxide film (SiO₂), into trenches formed in the semiconductor substrate 1. Thus, the adjacent active regions K are isolated from one another by the element formation regions 3.

The gate electrode 5 is a trench gate electrode that is embedded into a groove formed in the semiconductor substrate 1 and protrudes from the impurity diffusion layer 8. The gate electrode 5 is made of a multi-layer including a polycrystalline silicon film containing an impurity and a metal film.

The polycrystalline silicon film is formed by implanting an N-type impurity, such as phosphorus (P), while a film is formed by CVD (Chemical Vapor Deposition). Alternatively, a polycrystalline silicon film free of an impurity is formed first. Then, an N-type or P-type impurity may be ion implanted therein. A high-melting-point metal, such as tungsten (W), tungsten nitride (WN), or tungsten silicide (WSi), can be used for the metal film.

A gate insulating film 5a is formed between the gate electrode 5 and the semiconductor substrate 1. For example, silicon oxide (SiO₂), a multi-layered film containing silicon oxide and silicon nitride, or a High-K film (high-dielectric film) can be used for the gate insulating film 5a.

An insulating film (hereinafter, “sidewall”) 5b made of, for example, silicon nitride (Si₃N₄) is formed on a sidewall of a portion of the gate electrode 5 protruding from the semiconductor substrate 1. Additionally, an insulating film 5c made of, for example, silicon nitride, is formed on the gate electrode 5.

The impurity diffusion layers 8 including an N-type impurity, such as phosphorus (P), are formed immediately under the upper surface of the semiconductor substrate 1 which is separated into three regions by the two gate electrode 5.

The substrate contact plugs 9 are formed so as to contact the impurity diffusion layers 8. The substrate contact plugs 9 are positioned at the substrate contact portions 205c, 205a, and 205b. The substrate plug 9 is made of, for example, polycrystalline silicon.

A width of the substrate contact plug 9 in the X-direction is defined by the sidewalls 5b on the adjacent word wirings W. The substrate contact plug 9 has a self-alignment structure.

A bit-line contact plug 4A is formed so as to penetrate the inter-layer insulating film 4 covering the insulating film 5c on the gate electrode 5 and to electrically communicate with the substrate contact plug 9. The bit-line contact plug 4A is formed by, for example, depositing a tungsten (W) film over a barrier film (TiN/Ti) containing titanium (Ti) and titanium nitride (TiN).

A bit wiring 6 is formed so as to contact the bit-line contact plug 4A. The bit wiring 6 is made of, for example, a multi-layer containing tungsten nitride (WN) and tungsten (W).

An inter-layer insulating film 7 is formed so as to cover the bit wiring 6 and the inter-layer insulating film 4. Capacitor contact plugs 7A are formed so as to penetrate the inter-layer insulating films 4 and 7 and to contact the substrate contact plugs 9. The contact plugs 7A are positioned at the substrate contact portions 205b and 205c.

Thus, the two gate electrodes 5 function as gate electrodes of the two MOS transistors Tr1. The impurity diffusion layer 8 functions as an S/D region. Although the MOS transistors Tr1 including trench gate electrodes have been taken as an example of the first embodiment, another MOS transistor, such as a planar MOS transistor, may be used. Alternatively, a MOS transistor having a channel region on a side surface of a trench in a semiconductor substrate may be used.

Contact pads 10 are provided on the inter-layer insulating film 7 so as to electrically communicate with the contact plug 7A. The contact pad 10 is made of a multi-layered film containing, for example, tungsten nitride (WN) and tungsten (W).

A first inter-layer insulating film 11 is formed so as to cover the contact pads 10 and the inter-layer insulating film 7. The first inter-layer insulting film 11 is made of, for example, silicon nitride.

An upper electrode 15 is formed over the first inter-layer insulating film 11. The capacitors 30 are formed on the corresponding contact pads 10 inside the upper electrode 15. The capacitor 30 includes a cylindrical lower electrode 13, a first insulating film (capacitor insulating film not shown) covering a side surface of the cylindrical lower electrode 13, and the upper electrode 15 covering the first insulating film.

The lower electrode 13 is formed on the inner wall of the opening 12A penetrating the upper electrode 15. A bottom surface of the lower electrode 13 contacts the contact pad 10 to electrically communicate with the contact pad 10.

A first support portion 61 (14) fills space inside the cylindrical lower electrode 13. The second support portion 62 (14) contacts upper surfaces of the first support portions 61 (14) so as to connect multiple lower electrodes 13. Accordingly, the lower electrodes 13 are strongly supported, thereby preventing the lower electrodes 13 from collapsing even when the outer sidewalls of the lower electrodes 13 are exposed in the wet-etching process.

A third support portion 63 (14) fills space inside a groove wall 73 as explained later. A fourth support portion 64 (14) is formed so as to cover the third support portion 63 (14). The second support portion 62 contacts the fourth support portion 64. Accordingly, the lower electrodes 13 are strongly supported, thereby preventing the lower electrodes 13 from collapsing even when the outer sidewalls of the lower electrodes 13 are exposed in the wet-etching process.

The first to fourth support portions 61, 62, 63, and 64 are made of the same material, i.e., a second insulating film 14. Accordingly, the lower electrodes 13 are strongly supported, thereby preventing the lower electrodes 13 from collapsing even when the outer sidewalls of the lower electrodes 13 are exposed in the wet-etching process.

An inter-layer insulating film 20 is formed over the upper electrode 15. A wiring 21 is formed on the inter-layer insulating film 20. A surface protection film 22 is formed so as to cover the inter-layer insulating film 20 and the wiring 21. The wiring 21 is made of aluminum (Al), copper (Cu), or the like, and is electrically communicated with the upper electrode 15 in a non-depicted region.

As shown in FIG. 4B, the transistor formation layer 66 includes, the semiconductor substrate 1, the element isolation regions 3, a gate inter-layer insulating film 40, the inter-layer insulating films 4 and 7, which are deposited in this order.

The capacitor formation layer 67 includes: a layer including the first and second inter-layer insulating films 11 and 12, and the upper electrode 15; the inter-layer insulating film 20; and the surface protection film 22, which are deposited. The groove wall 73 is formed in the layer including the upper electrode 15 and the second inter-layer insulating film 12.

The contact pad 10 is disposed on the inter-layer insulating film 7. The first inter-layer insulating film 11 is formed so as to cover the contact pad 10 and the inter-layer insulating film 7.

The first inter-layer insulating film 11 is made of, for example, silicon nitride. The contact pad 10 is made of a multi-layer containing, for example, tungsten nitride (WN) and tungsten (W).

The upper electrode 15 is formed on the first inter-layer insulating film 11 in the main region 55 (inner side). The second inter-layer insulating film 12 made of silicon oxide or the like is formed on the first inter-layer insulating film 11 in the cell peripheral region 52 (outer side).

The groove wall 73 is formed on an inner wall of a groove 12B between the upper electrode 15 and the second inter-layer insulating film 12. The bottom surface of the groove wall 73 contacts the contact pad 10 so as to electrically communicate with the contact pad 10.

The groove wall 73 is formed in the cell peripheral region 56 so as to surround the main region 55. The third support portion 63 made of silicon nitride or the like fills space inside the groove wall 73. Accordingly, chemical solution is prevented from horizontally protruding into the peripheral circuit region 52 adjacent to the memory cell region 51 in the wet-etching process.

The fourth support portion 64 is formed so as to cover the upper surface of the third support portion 63 and to extend toward the main region 55 and the peripheral circuit region 52. Accordingly, chemical solution is prevented from protruding into the peripheral circuit region 52 in the wet-etching process for exposing the lower electrode 13.

Preferably, the fourth support portion 64 covers the peripheral circuit region 52 until the end of the wet etching process. Accordingly, chemical solution is prevented from protruding into the peripheral circuit region 52 in the wet-etching process for exposing the lower electrode 13.

The first to fourth support portions 61 to 64 are made of the same material, i.e., the second insulating film 14, thereby preventing the first to fourth support portions 61 to 64 from peeling from one another. Accordingly, the lower electrodes 13 are strongly supported, thereby preventing the lower electrodes 13 from collapsing even when the outer sidewalls of the lower electrodes 13 are exposed in the wet-etching process.

As shown in FIG. 2, the second support portion 62 contacts the fourth support portion 64, and thereby is strongly supported. Accordingly, the lower electrodes 13 are strongly supported, thereby preventing the lower electrodes 13 from collapsing even when the outer sidewalls of the lower electrodes 13 are exposed in the wet etching process.

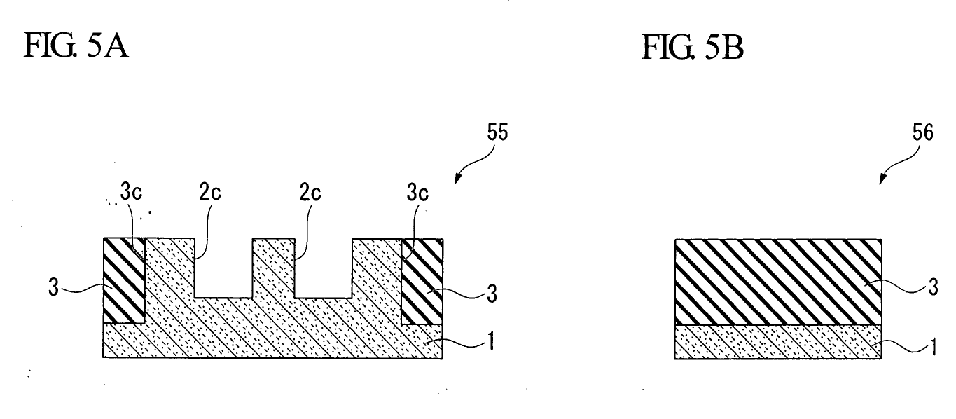

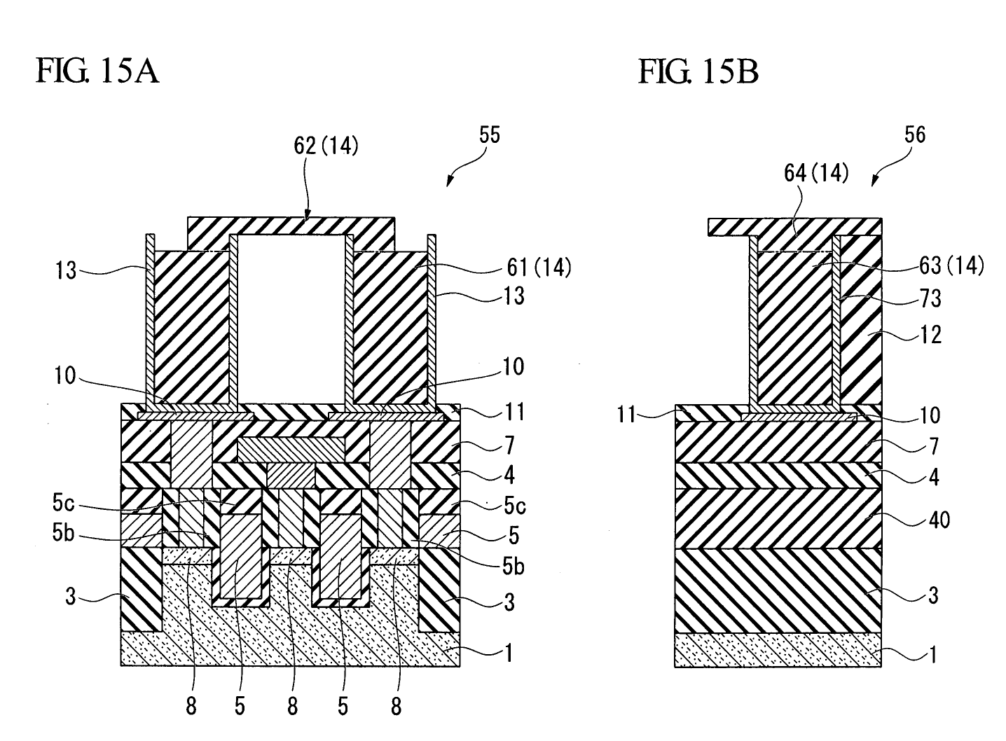

Hereinafter, a method of manufacturing the semiconductor device 50 of the first embodiment is explained with reference to FIGS. 5 to 16. FIGS. 5A to 15A are cross-sectional views taken along the line A-A′ shown in FIG. 2. FIGS. 5B to 15B are cross-sectional views taken along the line B-B′ shown in FIG. 2. If not specifically mentioned, processes of forming the memory cell region 51 and the cell peripheral region 52 are simultaneously explained hereinafter.

The semiconductor-device manufacturing method according to the first embodiment includes: a preliminary process of forming a transistor formation layer; a first process of forming lower electrodes and a groove wall; a second process of forming first to fourth support portions; a third process of exposing the lower electrodes; and a fourth process of forming an upper electrode.

The preliminary process of forming a transistor formation layer is explained first. Trenches 3c are formed in the semiconductor substrate 1 by etching the semiconductor substrate 1 using a mask (not shown) formed using a photoresist film. Then, the element isolation regions 3 are formed by STI (Shallow Trench Isolation) in which an insulating film is embedded into the trenches 3c.

Then, trenches 2c are formed in a similar manner. FIG. 5A is a cross-sectional view illustrating the element formation regions 3 having been formed. Regions defined by the element formation regions 3 become the active regions K. The trenches 2c are used for forming trench gate electrodes of the MOS transistors Tr1.

Then, the upper surface of the semiconductor substrate 1 is oxidized to form a thermal oxidization film made of silicon oxide (SiO₂) having a thickness of approximately 4 nm, thus forming the gate insulating film 5a. The thermal oxidization film on the main surface of the semiconductor substrate 1 may be removed in the following transistor forming process, and an illustration thereof is omitted.

Then, a polycrystalline silicon film containing an N-type impurity, such as phosphorus, is deposited over the gate insulating film 5a by CVD using monosilane (SiH₄) and phosphine (PH₃) as material gas. In this case, the polycrystalline silicon film has a thickness such that the trenches 2c for forming the gate electrodes are completely filled with the polycrystalline silicon film.

Alternatively, a polycrystalline silicon film free of an impurity may be formed first. Then, an N-type impurity such as phosphorus, or a P-type impurity such as boron may be implanted into the polycrystalline silicon film.

Then, a high-melting-point metal, such as tungsten, tungsten nitride, or tungsten silicide, is deposited in a thickness of approximately 50 nm on the polycrystalline silicon film by sputtering to form a metal film. The polycrystalline silicon film and the metal film formed in this manner will become the gate electrodes 5 through the following processes as explained layer.

Then, the insulating film 5c made of silicon nitride is deposited on the metal film in a thickness of approximately 70 nm by plasma CVD using monosilane and ammonia (NH₃) as material gas.

Then, a photoresist pattern (resist mask) for forming gate electrodes is formed on the insulating film 5c by photolithography. Then, the insulating film 5c is anisotropically etched using the resist mask.

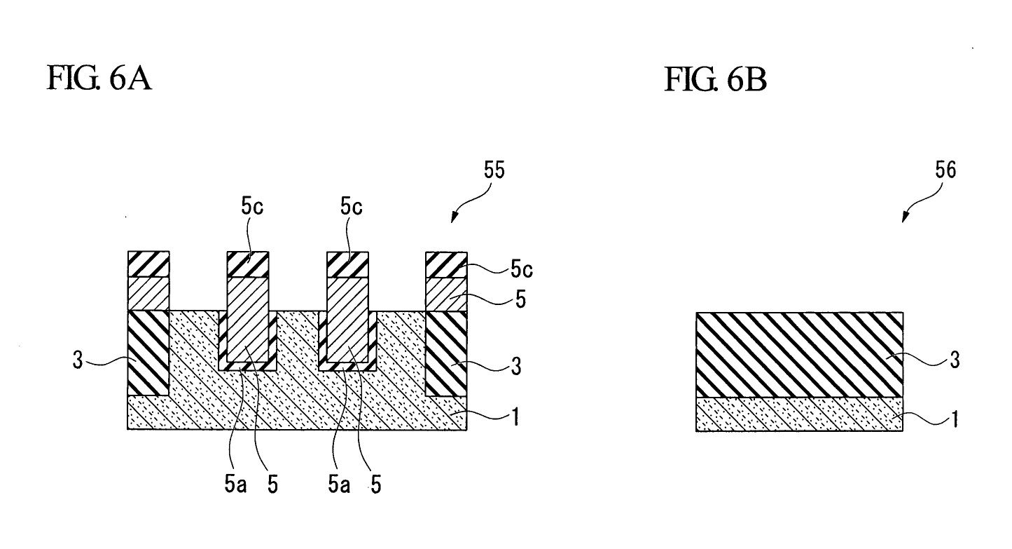

After the resist mask is removed, the metal film and the polycrystalline silicon film are etched using the insulating film 5c as a mask to form the gate electrodes 5 as shown in FIG. 6A. The gate electrode 5 functions as the word line shown in FIG. 3.

Then, an N-type impurity, such as phosphorus, is ion-implanted into the semiconductor substrate 1 not covered by the gate electrode 5 to form the impurity diffusion layer 8.

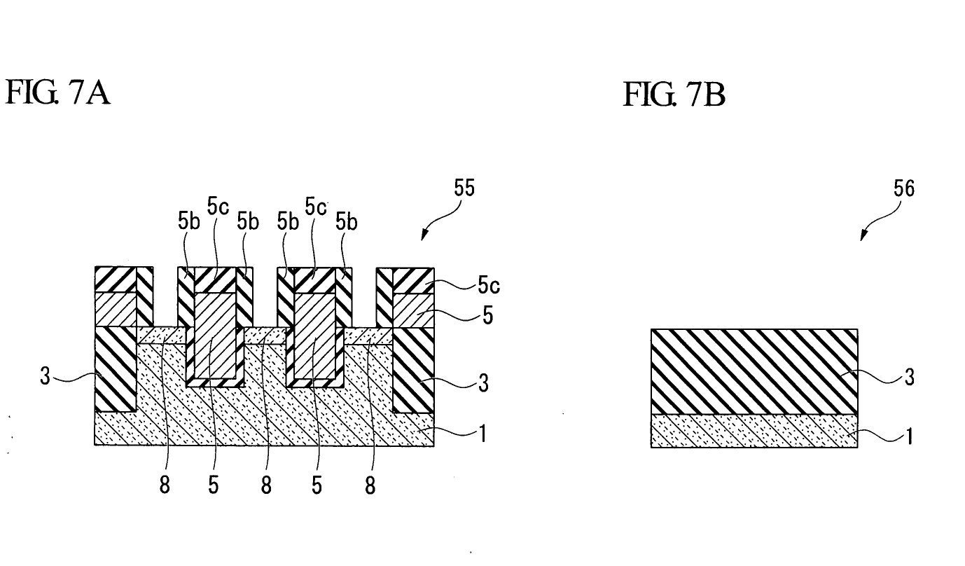

Then, a silicon nitride film is deposited by CVD in a thickness of approximately 20 nm to 50 nm so as to cover the upper surface of the semiconductor substrate 1, the gate electrode 5, and the insulating film 5c. Then, the silicon nitride film is etched back until the insulating film 5c is exposed. Thus, the sidewall 5b is formed on a side surface of the gate electrode 5, as shown in FIG. 7A.

Then, an inter-layer insulating film 40 made of silicon oxide is formed by CVD so as to cover the insulating film 5c and the sidewall 5b on the gate electrode 5. Then, an upper surface of the inter-layer insulating film 40 is polished by CMP (Chemical Mechanical Polishing) until the insulating film 5c is exposed. Thus, the upper surface of the inter-layer insulating film 40 which is not flat due to the gate electrode 5 can be planarized.

Then, a photoresist pattern (resist mask) having openings at positions corresponding to the substrate contacts 205a, 205b, and 205c shown in FIG. 3 is formed over the insulating film 5c by photolithography. Then, the gate inter-layer insulating film 40 is removed by anisotropic dry etching using the resist mask.

Thus, openings (holes) can be provided between the gate electrodes 5 by self-alignment using the insulating films 5b and 5c made of silicon nitride. The gate inter-layer insulating film 40 remains in the cell peripheral region 56 without being patterned.

Then, a polycrystalline silicon film containing phosphorus is deposited by CVD. Then, an upper surface of the polycrystalline silicon film is polished by the CMP until the insulating film 5c is exposed.

Thus, the substrate contact plugs 9 filling the openings are formed on the impurity diffusion layers 8. The polycrystalline silicon film is completely removed in the cell peripheral region 56, and the surface of the gate inter-layer insulating film 40 is exposed.

Then, the inter-layer insulating film 4 made of silicon oxide is deposited by CVD in a thickness of approximately 600 nm so as to cover the gate inter-layer insulating film 40, the insulating film 5c, and the substrate contact plugs 9.

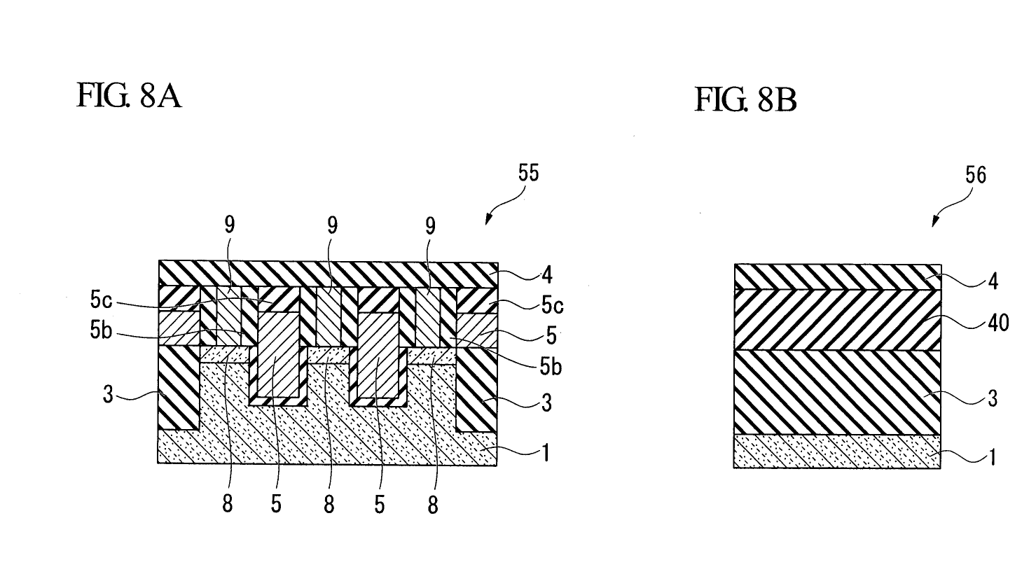

Then, an upper surface of the inter-layer insulating film 4 is polished and planarized by CMP until a thickness of the inter-layer insulating film 4 becomes approximately 300 nm as shown in FIGS. 8A and 8B.

Then, a contact hole is formed in the inter-layer insulating film 4 so that the upper surface of the substrate contact plug 9 positioned at the substrate contact portion 205a is exposed.

Then, a multi-layer including a barrier film such as TiN/Ti, and a tungsten film over the barrier film is deposited over the inter-layer insulating film 4 so as to fill the contact hole. Then, an upper surface of the multi-layer is polished by CMP until the inter-layer insulating film 4 is exposed, thus forming the bit-line contact plug 4A.

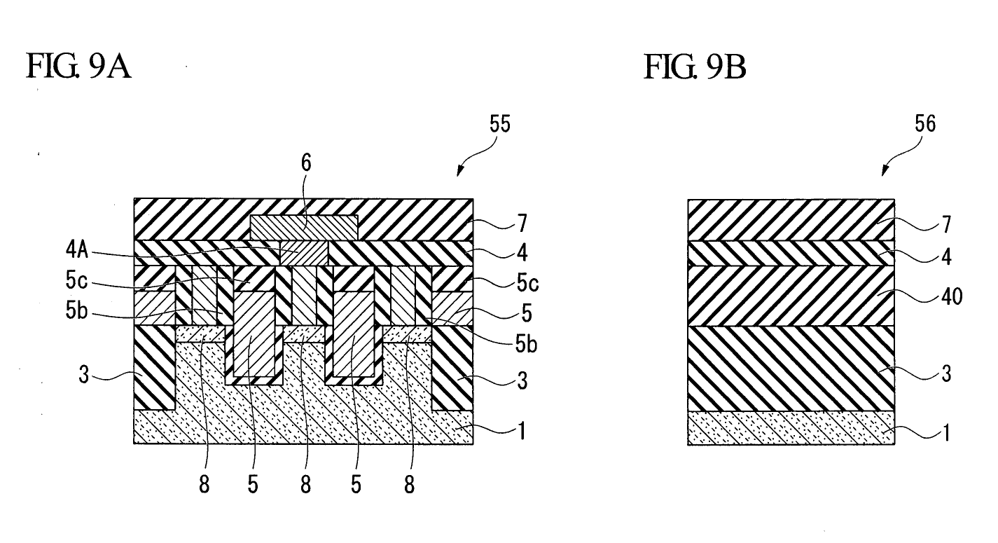

Then, the bit wiring 6 is formed on the first inter-layer insulating film 4 so as to contact the bit-line contact 4A. Then, the inter-layer insulating film 7 made of silicon oxide is formed so as to cover the bit wiring 6 and the first inter-layer insulating film 4, as shown in FIG. 9A.

Then, contact holes are formed so as to penetrate the inter-layer insulating films 4 and 7 and to expose the upper surfaces of the substrate contact plugs 9 positioned at the substrate contact portions 205b and 205c shown in FIG. 3.

Then, a multi-layer including a barrier film such as TiN/Ti and a tungsten film over the barrier film is deposited so as to fill the contact holes. Then, an upper surface of the multi-layer is polished by CMP until the first inter-layer insulating film 4 is exposed, thus forming the capacity contact plugs 7A.

Hereinafter, the first process of forming the lower electrodes and the groove wall is explained. Firstly, the contact pads 10 made of a multi-layered film containing tungsten are formed on the second inter-layer insulating film 7 so as to contact the contact plugs 7A.

The contact pad 10 is set to be larger in size than the bottom surface of the lower electrode of the capacitor that will be explained layer. The capacity contact pad 10 is also formed in the cell peripheral region 56.

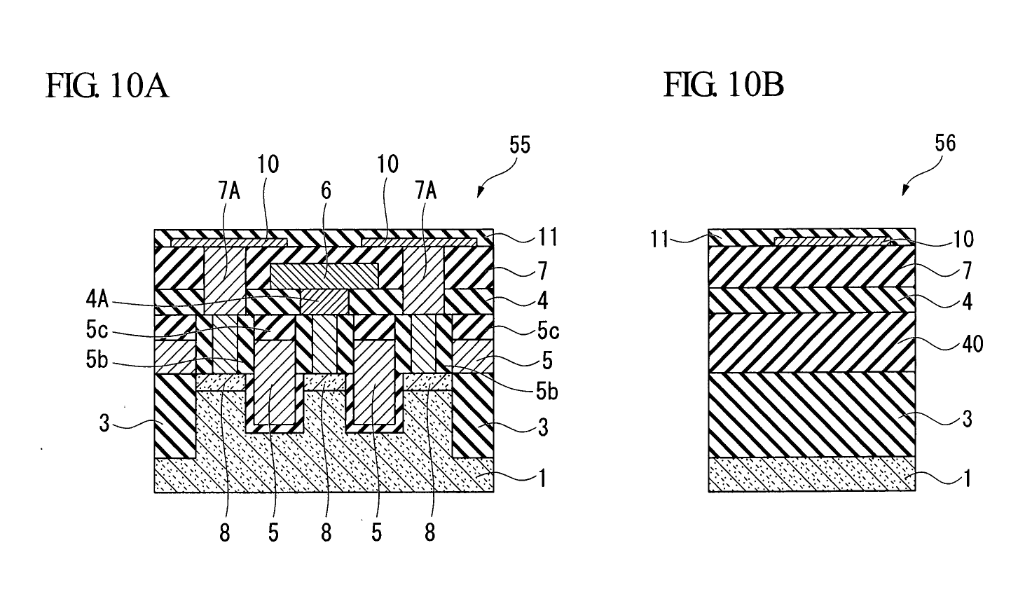

Then, the first inter-layer insulating film 11 made of silicon nitride is formed in a thickness of approximately 60 nm so as to cover the contact pad 10 and the second inter-layer insulting film 7, as shown in FIGS. 10A and 10B.

Then, the second inter-layer insulating film 12 made of silicon oxide or the like is deposited in a thickness of approximately 2 μm over the first inter-layer insulating film 11. Then, openings 12A are formed in the second inter-layer insulating film 12 by anisotropic dry etching so as to expose the upper surfaces of the contact pads 10.

The positions of the openings 12A correspond to those of capacitors to be formed. At the same time, the groove 12B is formed in the cell peripheral region 56 so as to surround the main region 55 as aforementioned.

Then, a titanium nitride film is deposited so as to cover side and bottom surfaces of the openings 12A and the groove 12B, but not to completely fill the openings 12A and the groove 12B.

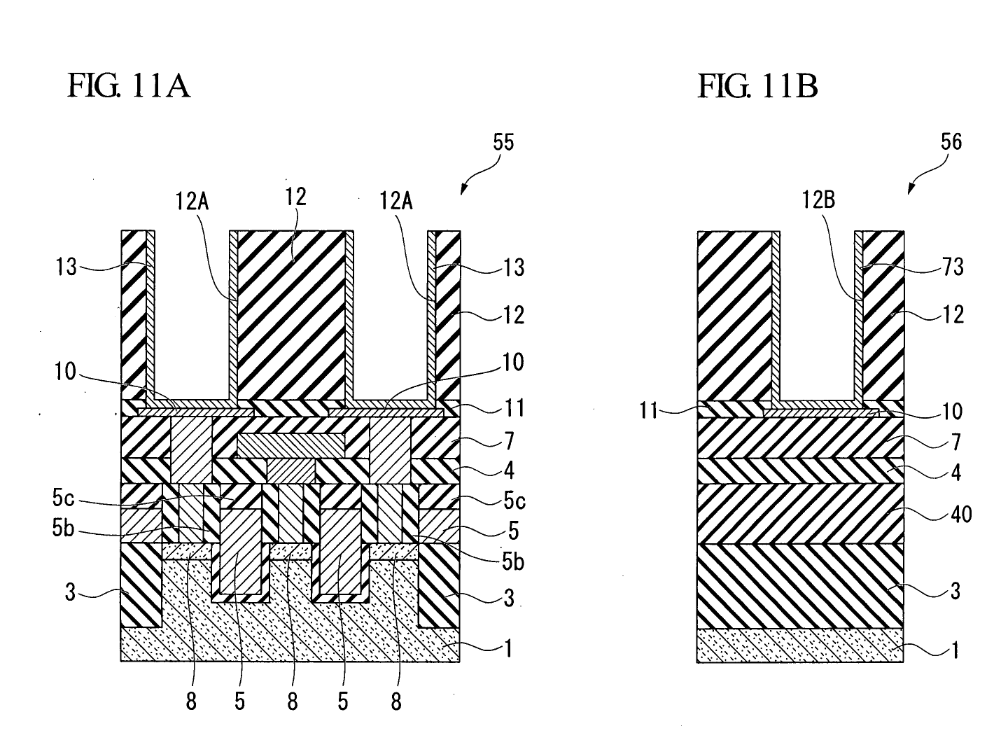

Then, the titanium nitride film on the second inter-layer insulating film 12 is removed by dry etching or CMP to form the cylindrical lower electrodes 13 and the groove wall 73 as shown in FIGS. 11A and 11B. A metal film other than the titanium nitride film may be used for forming the lower electrodes 13 and the groove wall 73.

Alternatively, a photoresist film or the like is provided to fill the openings covered by the cylindrical lower electrodes 13 and the groove covered by the groove wall 73, and then the titanium nitride film is removed by dry etching or CMP. Thus, the titanium nitride film filling the openings covered by the cylindrical lower electrodes 13 and filling the groove covered by the groove wall 73 can be protected. In this case, the photoresist film is removed after the titanium nitride film on the second inter-layer insulating film 12 is removed.

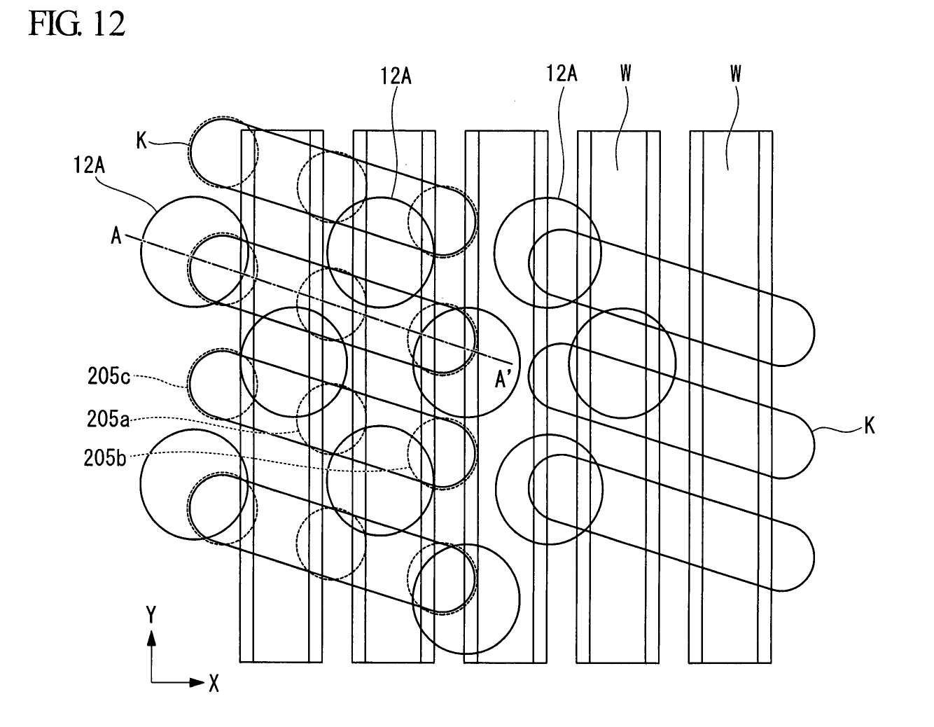

FIG. 12 is a plane view illustrating substantially the same portion shown in FIG. 3. The line A-A′ shown in FIG. 12 is the same as that shown in FIG. 3. The bit wirings or the like are not shown in FIG. 12.

As shown in FIG. 12, the openings 12A partially overlap the substrate contact portions 205b and 205c at both ends of the active region K. The lower electrodes 13 are electrically communicated with plugs provided on the substrate contact portions 205b and 205c through the contact pads 10 (not shown).

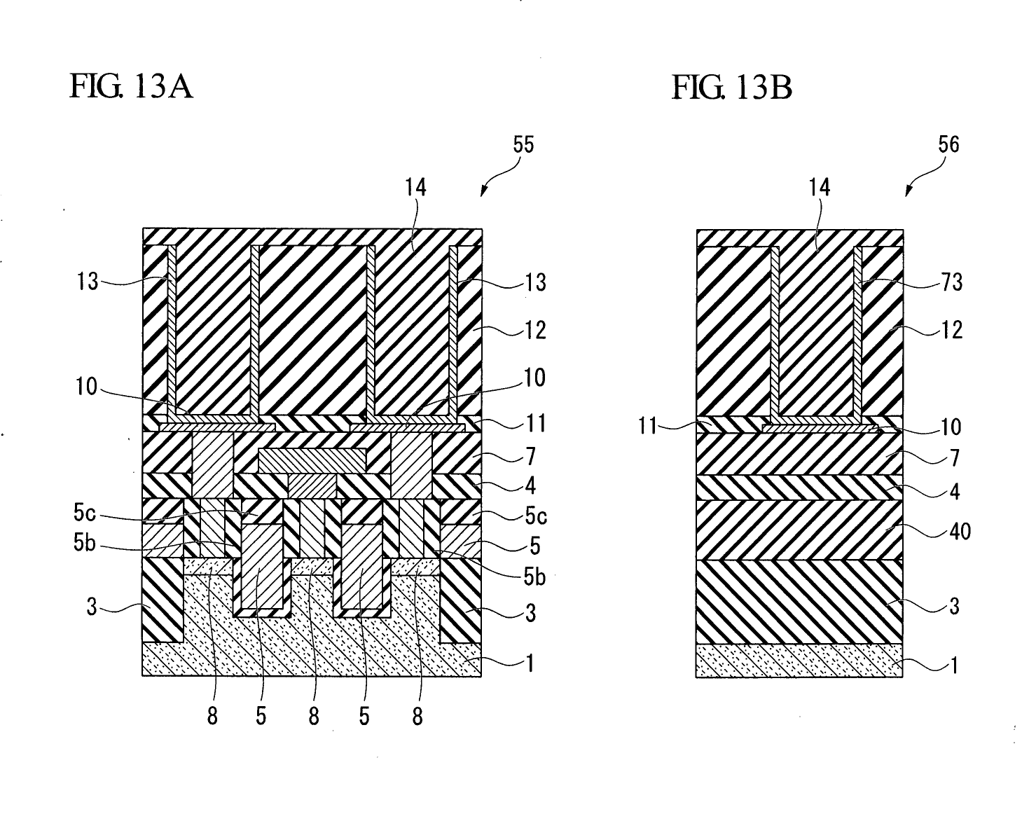

Hereinafter, the second process of forming the first to fourth support portions is explained. As shown in FIG. 13, the second insulating film 14 made of silicon nitride is deposited so as to fill the openings 12A and the groove 12B and to cover the second inter-layer insulating film 12.

Then, a photoresist pattern (resist mask) is formed on the second insulating film 14 by photolithography. The photoresist pattern has a frame portion covering the cell peripheral region 56 and line portions extending toward the X-direction to contact the frame portion. Then, the silicon nitride film is anisotropically etched using the resist mask to partially remove an upper surface of the second insulating film 14.

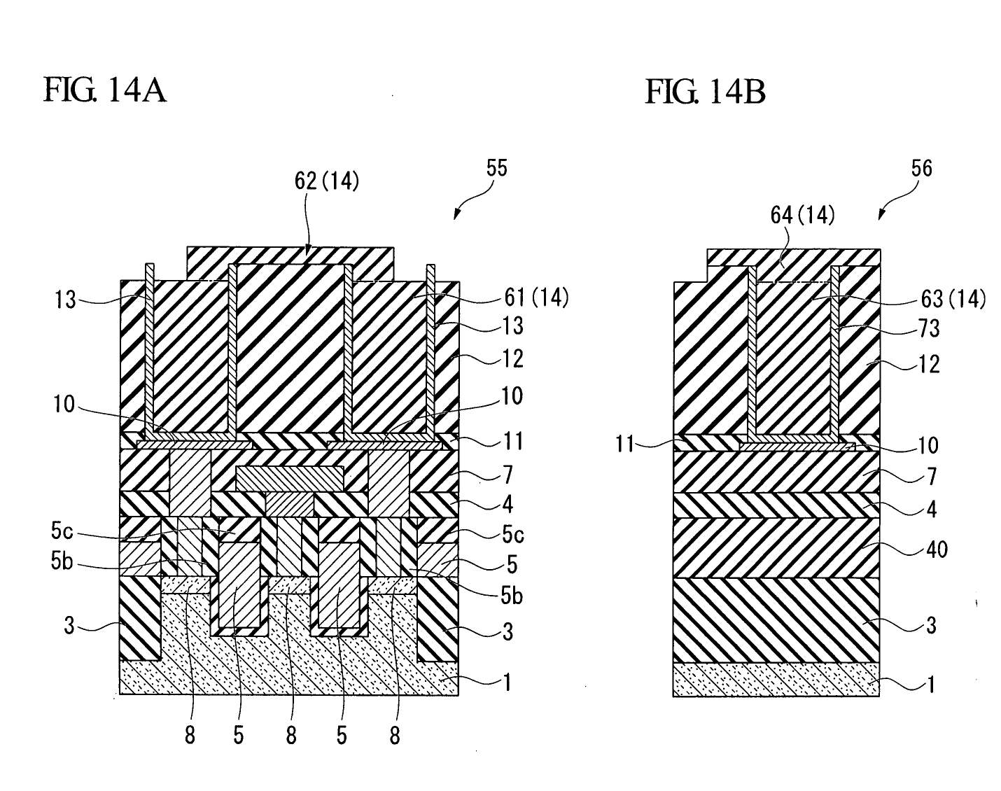

Thus, the first to fourth support portions 61 to 64 are formed as shown in FIGS. 14A and 14B. The first support portion 61 (41) fills the opening covered by cylindrical lower electrode 13. The second support portion 62 (14) is disposed on the upper surface of the first support portions 61 (14) while extending in the X-direction so as to connect the multiple lower electrodes 13. The third support portion 63 (14) fills the groove covered by the groove wall 73. The fourth support portion 64 (14) covers the upper surface of the third support portion 63 (14). The second support portion 62 (14) contacts the fourth support portion 64 (14).

Hereinafter, the third process of exposing the lower electrodes 13 is explained. Firstly, the second inter-layer insulating film 12 surrounded by the groove wall 73 is removed by wet etching using hydrofluoric acid (HF) so as to expose outer sidewalls of the lower electrodes 13.

In this case, the first inter-layer insulating film 11 made of silicon nitride serves as a stopper film against chemical solution upon the wet etching, thereby preventing the transistors Tr1 and the like in the transistor formation layer 66 from being etched, and therefore protecting the transistor formation layer 66.

The groove wall 73 surrounding the main region 55 is formed in the cell peripheral region 56. The third support portion 63 made of silicon nitride is provided to fill the groove covered by the groove wall 73. As a result, chemical solution can be prevented from penetrating into the peripheral circuit region 52 adjacent to the memory cell region 51.

Additionally, the fourth support portion 64 covers the upper surface of the third support portion 63, thereby preventing chemical solution from penetrating into the peripheral circuit region 52 in the wet-etching process.

Further, the fourth support portion 64 covers the peripheral circuit region 52, thereby preventing chemical solution from penetrating over the upper surface of the main memory unit 51 into the peripheral circuit region 52 when the wet etching process is carried out for a long time.

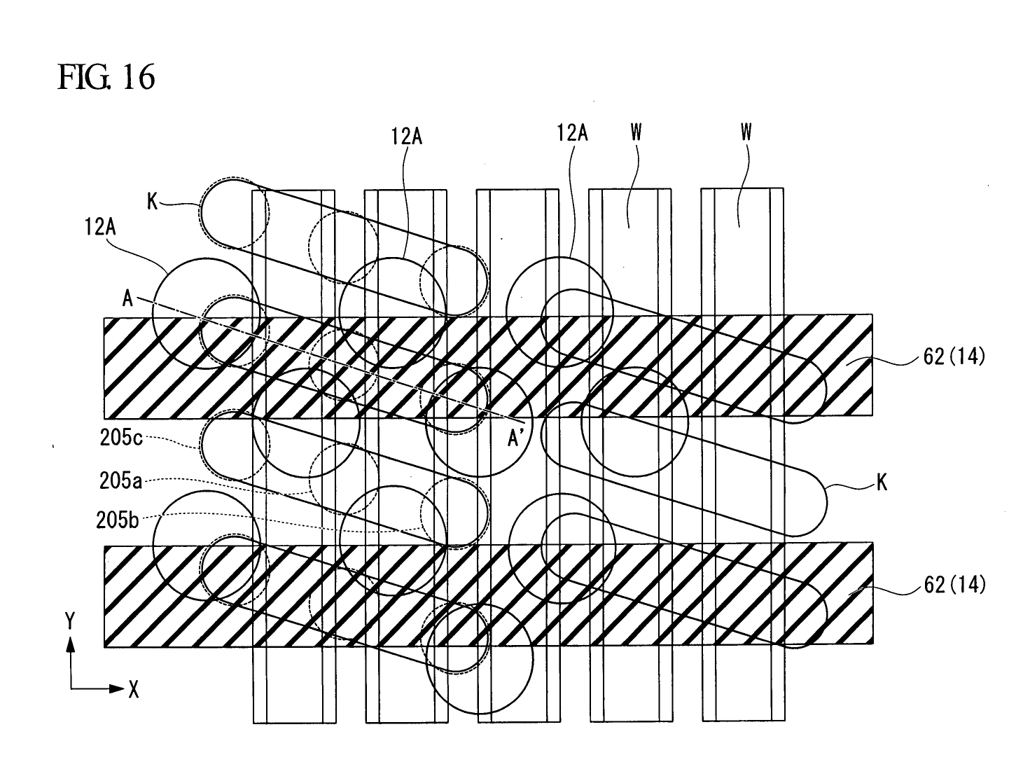

FIG. 16 is a plane view illustrating the same portion as that shown in FIG. 12 where the second support portions 62 are added. The second support portions 62 are in a straight line and extend toward the X-direction. The second support portions 62 are disposed at a predetermined pitch in the Y-direction.

The second support portion 62 partially overlaps the circular openings 12A. The cylindrical lower electrode 13 is formed on the inner surface of the opening 12A. The first support portion 1 fills the opening covered by the cylindrical lower electrode 13.

The second support portion 62 is connected to the upper surfaces of the first support portions 61 in the regions where the second support portion 62 overlaps the openings 12A. In these regions, the first and second support portions 61 and 62 are strongly connected to each other, thereby strongly supporting the lower electrodes 13 and therefore preventing the lower electrodes 13 from collapsing even when the outer sidewalls of the lower electrodes are exposed in the wet-etching process.

The second support portion 62 connects the adjacent lower electrodes 13, thereby strongly supporting the lower electrodes 13, and therefore preventing the lower electrodes 13 from collapsing even when the outer sidewalls of the lower electrodes 13 are exposed in the wet etching process.

As shown in FIG. 2, the second support portion 62 extends to the cell peripheral region 56 and contacts the fourth support portion 64 integrated with the third support portion 63. Accordingly, the second support portion 62 supported by the third and fourth support portions 63 and 64 strongly supports the lower electrodes 13 through the first support portions 61, thereby preventing the lower electrodes 13 from collapsing even when the outer sidewalls of the lower electrodes 13 are exposed in the wet etching process.

For the second support portion 62 to steadily support the lower electrodes 13 of the capacitors 30, the area where the second support portion 62 connects the first support portions 61 is preferably one fourth of the sectional area of the opening 12A or more.

An insulating film other than the silicon nitride film may be used for forming the first to fourth support portions as long as the etching rate of the insulating film is smaller than that of the second inter-layer insulating film 12, and the insulating film has sufficient resistance.

Hereinafter, the fourth process of forming the upper electrode is explained. Firstly, the first insulating film (capacitor insulating film not shown) is formed so as to cover the side surfaces of the lower electrodes 13. For example, a high dielectric film, such as a hafnium oxide film (HfO₂), a zirconium oxide film (ZrO₂), an aluminum oxide film (Al₂O₃), or a multi-layered film including those films, may be used as the capacitor insulating film.

Then, the upper electrode 15 made of titanium nitride or the like is formed so as to cover the first insulating film (capacitor insulating film) and the lower electrodes 13. Thus, the capacitor 30 including the cylindrical lower electrodes 13, the first insulating film covering the side surfaces of the lower electrodes 13, and the upper electrode 15 covering the first insulating film is formed.

The upper electrode 15 in the peripheral circuit region 52 is removed by dry etching. In this case, the fourth insulating film (silicon nitride film) on the peripheral circuit region 52 may be removed at the same time.

Then, the inter-layer insulating film 20 made of silicon oxide is formed so as to cover the upper electrode 15. Then, contact plugs (not shown) for applying electric potential to the upper electrodes 15 of the capacitors 30 are formed so as to penetrate the inter-layer insulating film 20.

Then, the wiring 21 made of aluminum (Al), copper (Cu), or the like is formed on the inter-layer insulating film 20 so as to contact the contact plugs. Then, the surface protection film 22 made of silicon oxynitride is formed so as to cover the wiring 21 and the inter-layer insulating film 20, as shown in FIG. 4. Thus, the semiconductor device (DRAM) 50 of the first embodiment is formed.

According to the semiconductor device manufacturing method of the first embodiment, the first to fourth support portions 61 to 64 for strongly supporting the lower electrodes 13 are formed, thereby preventing the lower electrodes 13 from collapsing even if the lower electrodes 13 are made higher. Consequently, a semiconductor device (DRAM) including a higher-capacitance capacitor while the lower electrodes 13 are made higher can be easily formed.

Additionally, the lower electrodes 13 having the high aspect ratio can be prevented from collapsing. Further, chemical solution can be prevented from penetrating into the peripheral circuit region 52 adjacent to the memory cell region 51.

Moreover, the connection strength of the first and second support portions 61 and 62 can be prevented from decreasing even if the outer sidewalls of the lower electrodes 13 are exposed in the wet etching process and the second support portion 62 is subjected to chemical solution for a long time, thereby preventing the lower electrodes 13 from collapsing. Therefore, the lower electrodes 13 are prevented from short-circuiting each other, which is caused by the lower electrodes 13 collapsing.

### Second Embodiment

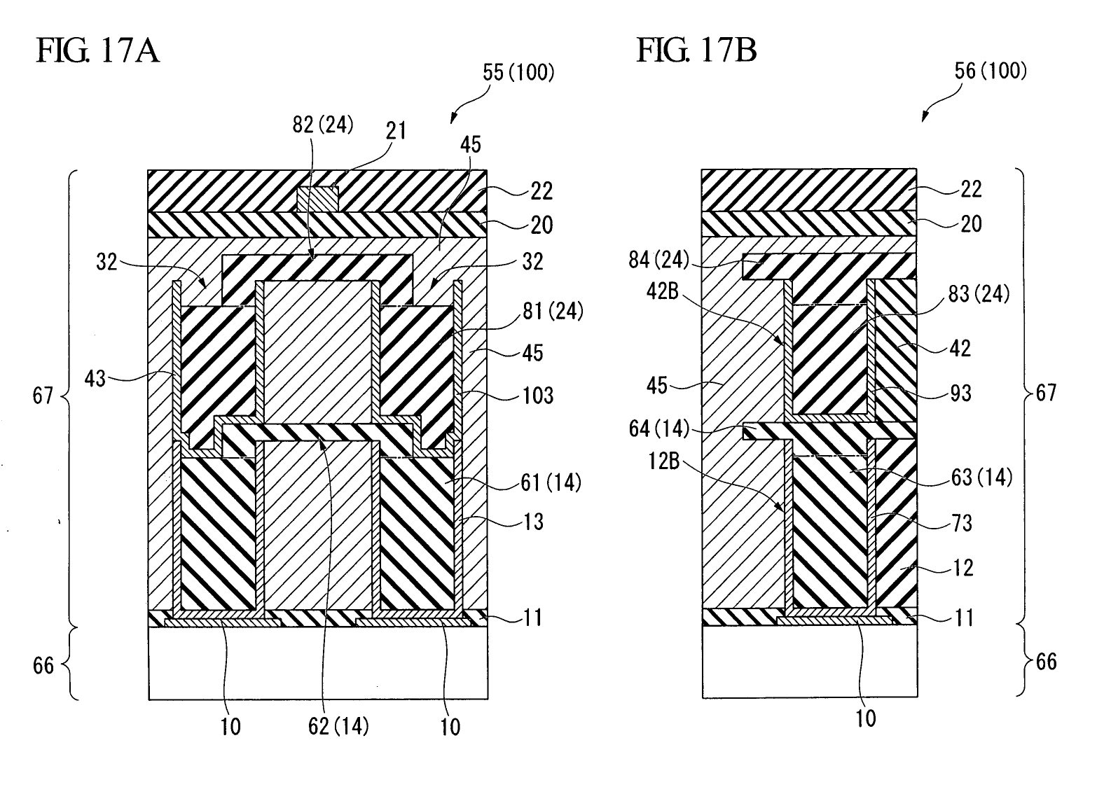

Hereinafter, a second embodiment of the present invention is explained. FIG. 17A is a cross-sectional view illustrating the main region 55 of a semiconductor device 100 according to the second embodiment. FIG. 17B is a cross-sectional view illustrating the cell peripheral region 56 of the semiconductor device 100.

The semiconductor device 100 has the same structure as the semiconductor device 50 of the first embodiment except that two cylindrical lower electrodes 13 and 103 are stacked, and two grooves 73 and 93 are stacked.

Each of the main and cell peripheral regions 55 and 56 has the transistor formation layer 66 and the capacitor formation unit 67 above the transistor formation layer 66. The transistor formation layer 55 has the same structure as that of the first embodiment. Therefore, explanations thereof are omitted here.

As shown in FIG. 17A, the cylindrical lower electrode 103 is stacked on the lower electrode 13 in the capacitor formation layer 67 of the main region 55. Thus, two or more lower electrodes are stacked to form a capacitor 32, thereby achieving greater capacitance than that in the case of one lower electrode.

Further, even if the height of the stacked lower electrodes increases, second support portions 62 and 82 are formed in different layers, thereby more strongly supporting the lower electrodes, and therefore achieving a capacitor having the higher aspect ratio.

In the capacitor formation layer 67 of the cell peripheral region 56, the groove walls 73 and 93 are stacked so as to surround the main region 55. Additionally, third support portions 63 and 103 made of silicon nitride fill the grooves covered by the groove walls 73 and 93, thereby preventing chemical solution from penetrating into the peripheral circuit region 52 adjacent to the memory cell region 51.

Hereinafter, a method of manufacturing the semiconductor device 100 is explained. After the lower electrodes 13, the groove wall 73, the first to fourth support portions 61 to 64 are formed by the semiconductor device manufacturing method of the first embodiment, before the second inter-layer insulating film is partially removed by wet etching, a third inter-layer insulating film is formed so as to cover the lower electrodes 13 and the groove wall 73.

Then, the lower electrodes 103 are formed so as to penetrate the third inter-layer insulating film and to connect to the lower electrodes 13. At the same time, the groove wall 93 is formed so as to penetrate the third inter-layer insulating film and to connect to the groove wall 73.

Then, the upper surface of the third insulating film covering the lower electrodes 103 and the groove wall 93 is etched, thus forming the first to fourth support portions 81 to 84 for supporting the lower electrodes 103. If more lower electrodes are to be stacked, the above process is repeated.

The first support portion 81 fills the opening covered by the lower electrode 103. The second support portion 82 contacts the upper surface of the first support portion 81 while extending in the X-direction to connect multiple lower electrodes 103. The third support portion 83 fills the groove covered by the groove wall 93. The fourth support portion 84 covers the third support portion 83.

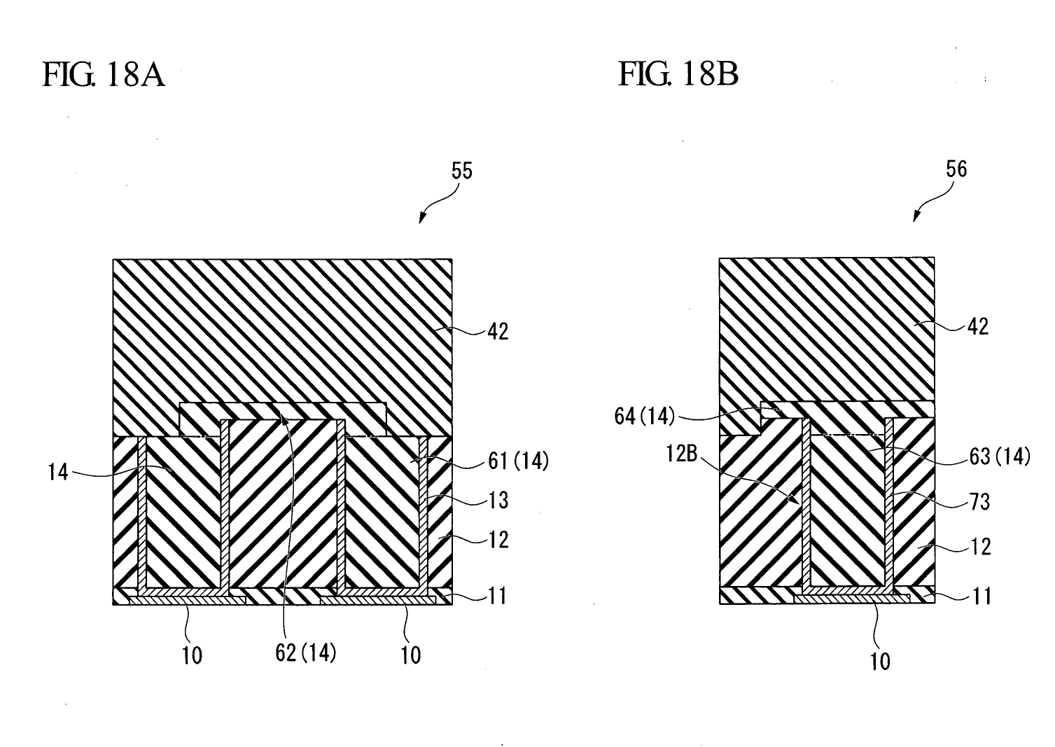

As shown in FIGS. 14A and 14B, processes of the method according to the second embodiment until the second insulating film is patterned to form the first to fourth support portions 61 to 64 are the same as those of the method of the first embodiment. Therefore, the following processes are explained hereinafter. The transistor formation layer is omitted in FIGS. 18 to 21.

The second insulating film 14 is patterned to form the first to fourth support portions 61 to 64. Then, a third inter-layer insulating film 42 made of silicon oxide or the like is deposited in a thickness of approximately 1 μm so as to cover the second insulating film 14 and the second inter-layer insulating film 12.

Then, openings 42A are formed by anisotropic dry etching in the third inter-layer insulating film 42 so as to partially expose the upper surfaces of the lower electrodes 13. The positions of openings 42A correspond to those of capacitors to be formed. Also in the cell peripheral region 56, the groove 42B is formed in the third inter-layer insulating film 42 so as to surround the main region 55.

Although the first and second support portions 61 and 62 are exposed upon the formation of the openings 42A and the groove 42B, dry-etching selectivity of the silicon oxide and the silicon nitride is adjusted for anisotropic etching so that the first and second support portions 61 and 62 made of silicon nitride remain.

Then, a titanium nitride film is deposited so as to cover side and bottom surfaces of the openings 42A and the groove 42B, but not to completely fill up the openings 42A and the groove 42B.

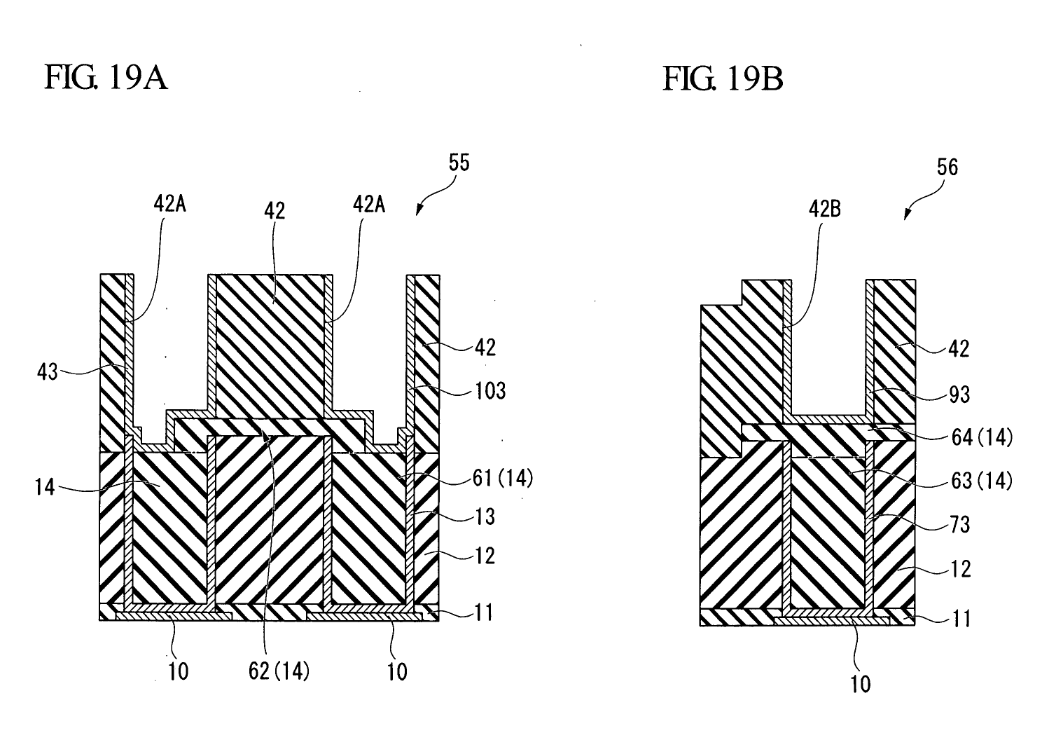

Then, the titanium nitride film on the third inter-layer insulating film 42 is removed by dry etching and CMP. Thus, the cylindrical lower electrodes 103 and the groove wall 93 made of titanium nitride are formed as shown in FIGS. 19A and 19B.

The bottom surface of the lower electrodes 103 are electrically communicated with the upper surface of the lower electrodes 13. Therefore, the lower electrodes 103 and 13 function as one lower electrode. Then, the second insulating film 24 made of silicon nitride is deposited so as to fill the openings 42A and the groove 42B and to cover the upper surface of the third inter-layer insulating film 42.

Then, a phororesist pattern (resist mask) having a line shape extending toward the X-direction is formed. Then, the silicon nitride film is anisotropically etched using the resist mask so as to partially remove the upper surface of the second insulating film 24.

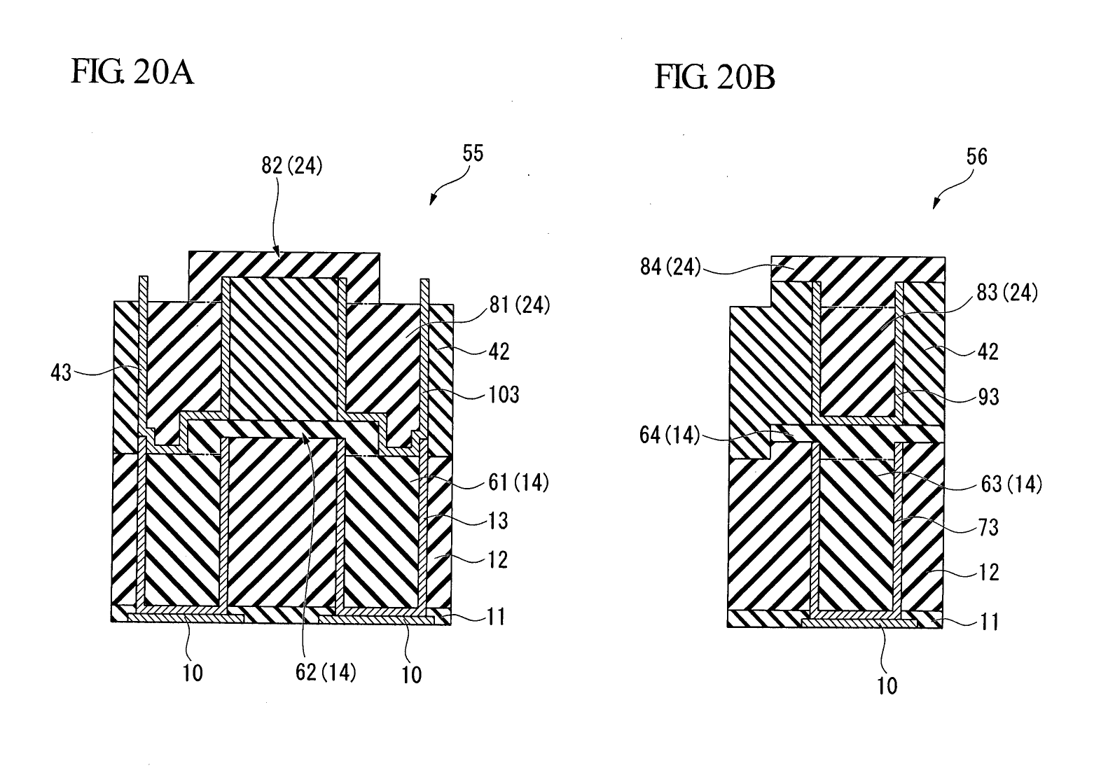

Thus, the first to fourth support portions 81 to 84 are formed as shown in FIG. 20. The first support portion 81 (24) fills the openings covered by the cylindrical lower electrode 103. The second support portion 82 (24) contacts the upper surfaces of the first support portions 82 (24) while extending toward the X-direction so as to connect multiple lower electrodes 83. The third support portion 83 (24) fills the groove covered by the groove wall 93. The fourth support portion 84 (24) covers the third support portion 83 (24) while the second support portions 82 contacts the fourth support portion 84.

Then, the second and third inter-layer insulating films 12 and 42 surrounded by the groove walls 73 and 93 are removed by wet etching with hydrofluoric acid so as to expose outer sidewalls of the lower electrodes 13 and 103.

In this case, the first inter-layer insulating film 11 made of silicon nitride serves as a stopper film against chemical solution in the wet etching process, thereby preventing the transistors or the like in the lower layer from being etched, and therefore protecting the transistor formation layer 66.

The groove walls 73 and 93 surrounding the main region 55 are formed in the cell peripheral region 56. Additionally, the third support portions 63 and 83 made of silicon nitride fill the grooves covered by the groove walls 73 and 93, respectively. Therefore, chemical solution can be prevented from protruding into the peripheral circuit region 52 adjacent to the memory cell region 51 in the wet etching process.

Further, the fourth support portion 84 covers the third support portion 83 while extending toward the main region 55 and the peripheral circuit region 52, thereby preventing chemical solution from protruding into the upper surface of the main region 55 toward the peripheral circuit region 52 in the wet etching process.

Moreover, the fourth support portion 84 covers the peripheral circuit region 52, thereby preventing chemical solution from protruding over the upper surface of the memory cell region 51 into the peripheral circuit region 52 in the wet etching process.

The fourth support portion 64 (lower layer) is not necessary as long as the fourth support portion 84 (upper layer) covers the peripheral circuit region 52. For this reason, the fourth support portion 64 may be removed when the support film 14 is patterned.

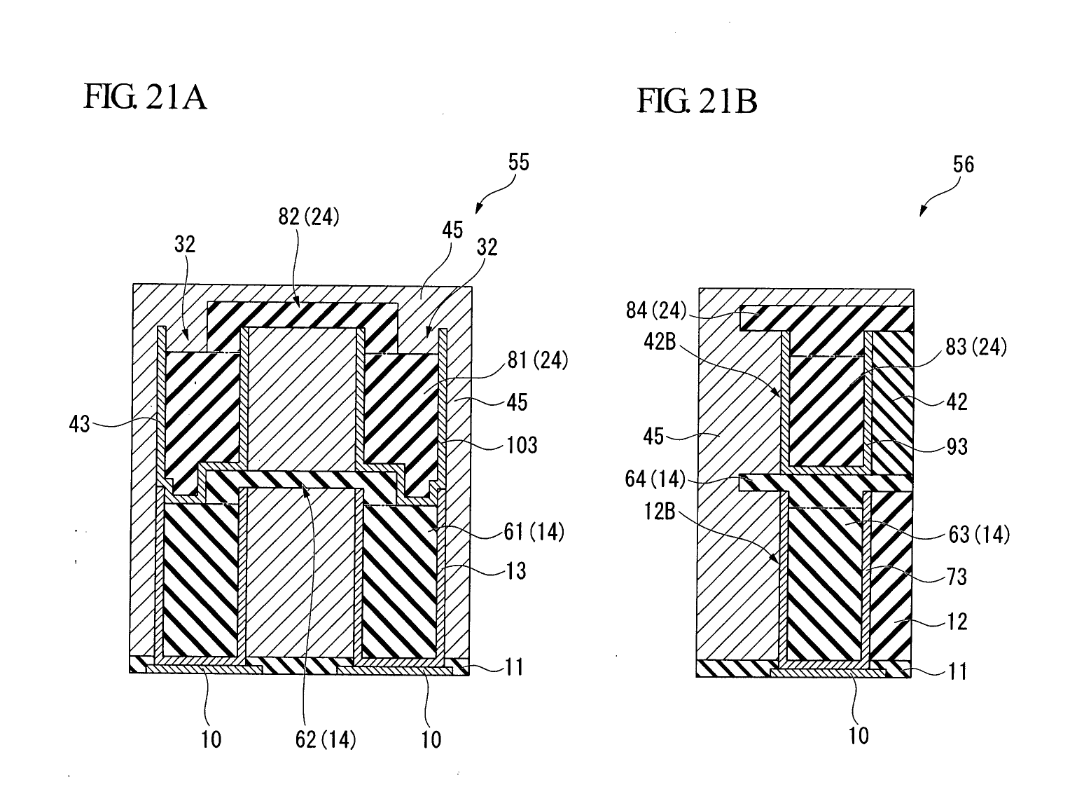

Then, the first insulating film (capacitor insulating film not shown) is formed so as to cover the lower electrodes 13 and 103. Then, upper electrode 45 made of titanium nitride or the like is formed so as to cover the first insulating film (capacitor insulating film) and the lower electrodes 13 and 103, as shown in FIGS. 21A and 21B.

Thus, a capacitor 32 including: the lower electrodes 13 and 103; the capacitor insulating film covering the side surfaces of the lower electrodes 13 and 103; and the upper electrode 45 covering the capacitor insulating film is formed. Similar to the first embodiment, the upper electrode 45 in the peripheral circuit region 52 may be removed. At the same time, the fourth support portion 84 in the peripheral circuit region 52 may be removed.

Then, an inter-layer insulating film 20 made of silicon oxide is formed so as to cover the upper electrode 45. Then, contact plugs (not shown) for applying electric potential to the upper electrode 45 of the capacitor 30 are formed.

Then, a wiring 21 made of aluminum (Al), copper (Cu), or the like is formed on the inter-layer insulating film 20. Then, a surface protection film 22 made of silicon oxynitride or the like is formed so as to cover the wiring 21 and the inter-layer insulating film 20 as shown in FIGS. 17A and 17B. Thus, the semiconductor device (DRAM) 100 is formed.

A semiconductor device of the second embodiment is not limited thereto, and may have a capacitor including three or more lower electrodes which are vertically stacked so as to have greater capacitance.

According to the semiconductor device 100, the semiconductor device 100 can include lower electrodes having a higher aspect ratio, and a capacitor having greater capacitance.

Additionally, the first to fourth support portions 61 to 64, and 81 to 84 strongly support the lower electrodes 13 and 103, thereby preventing the lower electrodes 13 and 103 from collapsing even when the outer sidewalls of the lower electors 13 and 103 are exposed in the wet etching process. Further, chemical solution can be prevented from protruding into the peripheral circuit region 52 adjacent to the memory cell region 51.

The present invention is applicable to semiconductor device manufacturing industries.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
a memory cell region; and
a peripheral circuit region;
wherein the memory cell region comprises a first region and a second region surrounding the first region, and
the first region comprises:
a plurality of first electrodes upwardly extending;
a plurality of first support portions upwardly extending along the plurality of first electrodes, and the plurality of first support portions each mechanically supporting corresponding one of the plurality of first electrodes; and
a second support portion contacting with the plurality of the first support portions, wherein the second support portion connects between each of the plurality of first electrodes.

2. The semiconductor device according to claim 1, wherein
the first region further comprises:
a second electrode disposed facing to each of the plurality of first electrodes with an intervention of an insulating film therebetween.

3. The semiconductor device according to claim 1, wherein
the second region comprises:
a first groove wall upwardly extending, the first groove wall surrounding the first region;
a third support portion extending along the first groove wall; and
a fourth support portion contacting with an upper surface of the third support portion, the fourth support portion being mechanically supported by the third support portion.

4. The semiconductor device according to claim 2, wherein the second support portion contacts with the fourth support portion.

5. The semiconductor device according to claim 1, wherein
the second support portion contacts with an upper surface of each of the plurality of first support portions, and
an area of a contacting portion between each of the plurality of the first support portions and the second support portion is one fourth of an area of the upper surface of each of the plurality of first support portions or more.

6. The semiconductor device according to claim 1, wherein
the first region further comprises:
a plurality of third electrodes upwardly extending over the plurality of first electrodes, each of the plurality of third electrodes being connected to corresponding one of the plurality of first electrodes;
a plurality of fifth support portions over the plurality of first support portions, the plurality of fifth support portions upwardly extending along the plurality of third electrodes, and the plurality of fifth support portions each mechanically supporting corresponding one of the plurality of third electrodes; and
a sixth support portion contacting with the plurality of fifth support portions, wherein the sixth support portion connects between each of the plurality of third electrodes.

7. The semiconductor device according to claim 6,
the first region further comprises:
a second electrode disposed facing to each of the plurality of first electrodes and each of the plurality of third electrodes with an intervention of an insulating film therebetween.

8. The semiconductor device according to claim 3, wherein
the second region further comprises:
a second groove wall upwardly extending over the first groove wall, the second groove wall surrounding the first region;
a seventh support portion extending along the second groove wall; and
an eighth support portion contacting with an upper surface of the seventh support portion, the eighth support portion being mechanically supported by the seventh support portion.

9. The semiconductor device according to claim 8, wherein the sixth support portion contacts with the eighth support portion.

10. The semiconductor device according to claim 8, wherein the eighth support portion extends toward the peripheral circuit region so as to cover the peripheral circuit region.

11. The semiconductor device according to claim 6, wherein the second and sixth support portions have line patterns each disposed in parallel.

12. The semiconductor device according to claim 2, wherein
the first region comprises a lower layer and a higher layer disposed over the lower layer,
the higher layer comprises the plurality of first electrodes, the second electrode, the first groove wall, and the first to fourth support portions, and
the lower layer comprises a plurality of transistors, wherein each of the plurality of first electrodes electrically connects to corresponding one of the plurality of transistors.

13. The semiconductor device according to claim 1, wherein each of the plurality of first electrodes has a cylindrical shape, each of the plurality of first support portions filling a center region of the cylindrical shape

14. The semiconductor device according to claim 6, wherein each of the plurality of first and third electrodes has a cylindrical shape.

15. The semiconductor device according to claim 8, wherein the first to fourth support portions are made of a first insulating film, and the fifth to eighth support portions are made of a second insulating film.

16. The semiconductor device according to claim 8, wherein the plurality of first to fourth electrodes and the first and second groove walls are made of the same material.

17. A method of manufacturing a semiconductor device, comprising:
forming a plurality of first openings and a first groove in a first insulating layer so as to penetrate the first insulating layer, the first groove surrounding the plurality of first openings;
forming a plurality of first electrodes and a first groove wall, the plurality of first electrodes covering at least side surfaces of the plurality of first openings, and the first groove wall covering at least a side surface of the first groove;
forming a first support film on the plurality of first electrodes and the first groove wall;
forming a plurality of first support portions, a second support portion, a third support portion, and a fourth support portion by removing a part of the first support film, each of the plurality of first support portions being disposed in the plurality of first openings, the third support portion being disposed in the first groove, the second support portion contacting with each of upper surfaces of the plurality of first support portions, the fourth support portion contacting with an upper surface of the third support portion, the second support portion contacting with the fourth support portion, and the second support portion connecting between each of the plurality of first electrodes;
removing a part of the first insulating layer to expose outer side walls of the plurality of first electrodes;
forming a second insulating layer on a surface of the plurality of first electrodes; and
forming a second electrode on the second insulating layer.

18. The method according to claim 17, wherein removing a part of the first insulating layer is performed by wet etching, an etching speed of the first insulating layer being faster than an etching speed of the first support portion at performing the wet etching.

19. The method according to claim 17, further comprising:
forming a plurality of third electrodes on the plurality of first electrodes before forming the second insulating layer, each of the third electrodes directly connected to corresponding one of the plurality of first electrodes, wherein each of the third electrodes are hold by the second support film.

20. The method according to claim 19, wherein each of the third electrodes has a cylindrical shape, and a part of the second support film fills a center region of the cylindrical shape.
